(19) United States
(12) Patent Application Publication
(10) Pub. No.: US 2025/0347028 A1
(43) Pub. Date: Nov. 13, 2025

(54) SUPERCONDUCTIVITY IN HYPERDOPED GE BY MOLECULAR BEAM EPITAXY

(71) Applicant: New York University, New York, NY (US)

(72) Inventors: Javad SHABANI, Briarcliff Manor, NY (US); Patrick J. STROHBEEN, New York, NY (US)

(73) Assignee: New York University, New York, NY (US)

(21) Appl. No.: 19/199,807

(22) Filed: May 6, 2025

Related U.S. Application Data
(60) Provisional application No. 63/643,880, filed on May 7, 2024.

(51) Int. Cl. C30B 23/02; C30B 29/06; C30B 29/08; C30B 33/00; C30B 33/02; H01L 21/02

(52) U.S. Cl. CPC C30B 23/025; C30B 29/06; C30B 29/08; C30B 33/005; C30B 33/02; H01L 21/02381; H01L 21/02532; H01L 21/0257; H01L 21/02631

(57) ABSTRACT

A method can include co-depositing Germanium and Gallium on a Germanium substrate to hyperdope Germanium at room temperature. The method can include depositing Silicon on the Germanium and Gallium to either alloy or cap the Germanium and Gallium. The hyperdoped Germanium can have superconductivity properties.

### CROSS-REFERENCE TO RELATED APPLICATIONS

The present application claims priority to U.S. Provisional Patent App. No. 63/643,880, filed on May 7, 2024, the disclosure of which is incorporated herein by reference in its entirety and for all purposes.

### STATEMENT OF GOVERNMENT INTEREST

This invention was made with government support under FA9550-21-1-0338 awarded by Air Force Office of Scientific Research. The government has certain rights in the invention.

### TECHNICAL FIELD

The present disclosure relates generally to superconductivity in hyperdoped Ge formed by molecular beam epitaxy.

### BACKGROUND

High-quality thin films of covalent superconducting material are enticing for pushing towards up-scaling current state-of-the-art quantum devices. Proposals calling for highly scalable device platforms such as cryogenic complementary metal-oxide-semiconductor (“CMOS”) circuitry or qubit architectures have emerged as a new challenge in finding materials such as Si or Ge for devices with superior performance at cryogenic temperatures. Additionally, covalent superconductors offer a characteristic in that high-quality fully homoepitaxial Josephson junctions can be created in the growth direction. Thus, drawing inspiration from the original superconducting qubits one can begin to consider qubit designs that make use of the out-of-plane degree of freedom such as the recently studied merged-element transmon, or “Mergemon”. Such designs have already shown through preliminary evaluations the impact of the superconductor-semiconductor interface on the observed information coherence times. It is projected that high quality epitaxial interfaces will solve this problem, putting forth a strong proposal for new material and device applications. Thus, further efforts must be made into developing highly compatible superconducting materials as qubit density requirements become more stringent.

Superconductivity in group IV semiconductors has been presented in diamond, silicon, and germanium previously, though these studies use high energy synthesis techniques (e.g., ion implantation) and many questions remain to be investigated. Particularly, when hyperdoping Ge with high energy Ga ion beams, the origin of superconductivity has remained controversial due to high energies driving possible phase segregation. For example, typically a thick silicon oxide layer is first deposited to protect the surface during the implantation process. After implantation and subsequent flash annealing at high temperature to activate the Ga acceptors, superconductivity is attained. However, if the protective oxide layer is etched away, the superconducting state disappears. This has resulted in the hypothesis that the Ga-metal is diffusing to the SiON/Ge interface and coalescing into a percolated network of metallic Ga, which is in itself an elemental Bardeen-Cooper-Schrieffer (BCS) superconductor even in a confined state.

### SUMMARY

One aspect of the present disclosure is directed towards a method. The method can comprise co-depositing, on a germanium substrate, a gallium-doped germanium layer at room temperature and depositing, on the gallium-doped germanium layer, a first additional layer.

In some implementations, the gallium-doped germanium layer is hyperdoped with gallium. The first additional layer can be a capping layer. The germanium substrate, the gallium-doped germanium layer, and the first additional layer can be annealed. The first additional layer can be deposited halfway through the co-depositing of the gallium-doped germanium layer. The first additional layer can have a thickness of less than 1 nm. The first additional layer can be an alloying layer.

In some implementations, the first additional layer can have a thickness between 1 to 2 nm, inclusive. The first additional layer can be a spacer layer. The first additional layer can include germanium.

In some implementations, the second additional layer can be deposited on the gallium-doped germanium layer. The second additional layer can be a capping layer. The co-depositing can occur at room temperature. The co-depositing and depositing can occur by molecular beam epitaxy (MBE). The co-depositing can occur under ultra-high vacuum (UHV).

Another aspect of the present disclosure can be directed towards a method. The method can include depositing, via a gallium flux and a germanium flux, gallium and germanium on a germanium substrate at room temperature, wherein deposition of the gallium and germanium forms a germanium layer hyperdoped with gallium. The method can include depositing, via a silicon flux, a silicon cap on the germanium layer hyperdoped with gallium. The method can include annealing the germanium substrate, the germanium layer hyperdoped with gallium, and the silicon cap.

In various implementations, the method can include oxidizing, after depositing the silicon cap and before annealing, the silicon cap, the germanium, layer hyperdoped with gallium, and the germanium substrate. The germanium layer hyperdoped with gallium can have a ratio of 1E12 to 6E12, inclusive, of gallium atoms per centimeter squared area of germanium. The annealing of the germanium substrate can be flash annealing at a temperature greater than room temperature.

Another aspect of the present disclosure can be directed towards a method. The method can include forming, by depositing gallium and germanium on a germanium substrate, a first germanium layer hyperdoped with gallium. The method can include forming, by depositing silicon, a first silicon layer on the first germanium layer hyperdoped with gallium. The method can include forming, by depositing gallium and germanium, a second germanium layer hyperdoped with gallium on the first silicon layer. The method can include forming, by depositing silicon, a second silicon layer on the second germanium layer hyperdoped with gallium.

In various implementations, at least of the first germanium layer hyperdoped with gallium, the first silicon layer, the second germanium layer hyperdoped with gallium, or the second silicon layer can be formed by molecular beam epitaxy (MBE). At least one of of the first germanium layer hyperdoped with gallium, the first silicon layer, the second germanium layer hyperdoped with gallium, or the second silicon layer can be formed at room temperature.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF THE FIGURES

The foregoing and other features of the present disclosure will become more fully apparent from the following description and appended claims, taken in conjunction with the accompanying drawings. Understanding that these drawings depict only several implementations in accordance with the disclosure and are therefore not to be considered limiting of its scope, the disclosure will be described with additional specificity and detail through use of the accompanying drawings.

FIG. 1 is a method of hyperdoping Ge.

FIG. 2 is a schematic overview of growth Method A.

FIG. 3 is a schematic overview of growth Method B.

FIG. 4A is a long-range bright field (“BF”) cross-sectional STEM images of a Ga-segregated Ge film scan showing significant segregation and agglomeration of Ga-droplets.

FIG. 4B is a zoomed-in bright field (“BF”) cross-sectional STEM images of a Ga-segregated Ge film on region indicated in FIG. 4A showing the triple interface of epoxy (vacuum), Ga-droplet, and underlying Ge.

FIG. 4C is a bright field (“BF”) cross-sectional STEM images of a Ga-segregated Ge film energy dispersive spectroscopy (EDS) map of region denoted by a box in FIG. 4A of the interface between a droplet and the substrate.

FIG. 5A is a high-resolution TEM image and shows the general film structure of a crystalline, hyperdoped Ge film.

FIG. 5B is a zoomed-in region indicated in FIG. 3 and presents the epitaxial interface between the hyperdoped region and the underlying Ge buffer.

FIG. 5C is an EDS elemental mapping of a zoomed-out region showing elemental composition of the film and hillocks. Yellow pixels are Si, red is Ge, and cyan is Ga.

FIG. 6A shows sheet resistance vs. temperature (black) and magnetic field (red, at 15 mK) of a sample grown using Method A.

FIG. 6B shows sheet resistance vs temperature (black) and magnetic field (red, at 15 mK) of a sample grown using Method B.

FIG. 7 shows a schematic of an example gallium-doped germanium material, in accordance with some embodiments of the present disclosure.

FIG. 8 is a flow diagram of an example method of forming hyperdoped Ge.

FIG. 9 is a flow diagram of an example method of forming hyperdoped Ge.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Superconductivity is a property where certain materials can conduct electricity with no electrical resistance below a material-specific critical temperature such as cryogenic temperatures. An electrical current can flow indefinitely through a superconductor, e.g., a material that exhibits superconductivity. Materials that exhibit superconductivity can also expel magnetic fields, e.g., Meissner Effect, and become diamagnetic. Superconductors can be diamagnetic below a material-specific critical magnetic field value.

Molecular beam epitaxy (MBE) can be a process that grows materials under ultra-high vacuum conditions on a heated crystalline substrate. MBE is an epitaxial process wherein layers of a material can be deposited sequentially onto the substrate. Growing materials in ultra-high vacuum conditions can ensure purity of the material grown by MBE. MBE can grow thin films with an atomic layer precision. Growing materials can occur in a growth chamber of the MBE system. Beams can deposit atoms of an element onto the heated crystalline substrate to grow the material. MBE can start with preparing the substrate by cleaning the substrate to ensure purity and proper epitaxial growth. The cleaned substrate can then be loaded into a vacuum chamber for growing materials in a MBE system. The substrate can then be heated to grow additional materials on the substrate. The materials to be deposited on the substrate can be heated by effusion cells or electron beam evaporators to create a flux of atoms or molecules to deposit the materials on the substrate. This deposition process can occur under ultra-high vacuum conditions to prevent contaminants from entering the growth chamber. Layers of the material can be sequentially deposited on the substrate at an atomic-level precision. The substrate can then be cooled down gradually to room temperature and removed from the growth chamber.

Germanium (Ge) is a semiconductor at room temperature. Doping germanium with gallium (Ga) can form a p-type semiconductor. Doping semiconductors can increase conductivity of the semiconductor by adding impurities with a different number of valence electrons, e.g., Ga has 3 and Ge has 4 valence electrons. When doped with Ga, germanium can become superconducting below a critical temperature. The critical temperature can be measured under vacuum conditions (e.g., less than 1E-4 mbar), but the superconducting phase would still exist at atmospheric pressure (e.g., 1E3 mbar). Superconductivity in Ga-doped germanium can be achieved via MBE. The superconducting phase of the Ga-doped germanium can be sensitive to processing conditions, and high temperature flash anneals can strongly promote Ga-segregation in the matrix. Furthermore, the MBE deposition process can enable carrier activation, e.g., make dopant atoms electrically active, even without a post-anneal in which superconductivity is attained. Ga-doped germanium can also be fabricated by ion implantation. Ion implantation accelerates dopant atoms into a wafer where the dopant atoms penetrate the wafer material to fabricate a doped material. Other materials such as group III elements (e.g., aluminum, boron) or group IV elements (e.g., carbon, silicon) on the periodic table can also be doped via MBE deposition. However, doping of these materials would have a different growth process due to the differences in chemistry. Hyperdoped Ge with Ga can be fabricated on Ge wafers with a composition. The composition can be SiₓGe₁₋ₓ where x is less than or equal to 0.2.

The hyperdoped Ge with Ga material can exhibit a critical temperature of _{Tc}=5.27 K and critical field values of

$${B}_{c}^{⊥} = 0.43 T , {B}_{c}^{‖} = 1.03 T$$

at 15 mK. The interface between un-doped Ge and the hyperdoped Ge layer can remain highly coherent after growth. The existence of an interface illustrates control that the MBE process has over the location of Ga atoms within the Ge substrate. This also enables hyperdoped Ge with Ga to be used in a larger variety of device structures. The interface also illustrates that the Ga atoms are not diffusing significantly across the interface and altering the crystallinity of the Ge substrate. A superconducting phase of the hyperdoped material can be coherent to the Ge substrate by suppressing phase segregation through temperature control. For example, properly monitoring and controlling the substrate temperature during the growth process can help suppress the diffusion of Ga into the Ge substrate which shows control over the location of the Ga atoms within the Ge matrix.

Embodiments described herein relate generally to MBE growth of superconducting hyperdoped Ga: Ge, e.g., gallium (Ga) and germanium (Ge), thin films. Ga-segregation can be suppressed, and a superconducting phase can be obtained under appropriate growth conditions. Distinctive signatures between superconductivity can be originated from Ga-metal as well as dispersive hyperdoping which can be found through a combined electrical and structural analysis.

Electrical measurements of the thin films were conducted in an Oxford Triton pulse-tube dilution refrigerator with a base temperature of 15 mK and magnetic field capabilities up to 12T. Measurements were collected using a standard Van der Pauw wiring configuration on square pieces from near a center of each wafer. On-chip contacts were annealed In-Sn eutectic at each of four corners of the thin films.

### Hyperdoped Ge by MBE Methods

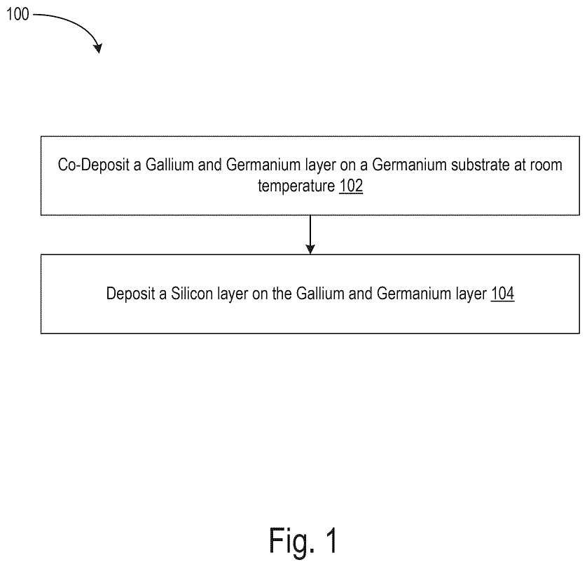

FIG. 1 depicts a method 100 of hyperdoping Ge.

At 102, the method 100 can include co-depositing a Ga and Ge to create a Ga-doped Ge layer on a Ge substrate. Co-depositing the layer can be done by molecular beam epitaxy (MBE). MBE can be a process of depositing crystalline layers of materials with an atomic precision in an ultra-high vacuum environment. MBE can grow one epitaxial layer of a material at a time. The epitaxial layer can be a layer of material deposited on a substrate. The substrate can be a single-crystalline substrate (e.g., (001)-orientation substrate). Co-depositing Ga and Ge can be conducted at room temperature. Co-depositing Ga and Ge can create a gallium-doped germanium layer. Co-depositing Ga and Ge can create a hyperdoped Ge layer. Hyperdoping can be doping a material beyond a solubility limit of dopants, e.g., Ga, in a material, e.g., Ge. Co-depositing the layer can include an interface between an undoped Ge substrate and the hyperdoped Ge layer. Hyperdoping can be doping beyond a solubility limit of a substrate (e.g., the Ge substrate). The solubility limit can change based on the substrate. For example, a maximum equilibrium solubility of Ga in Ge is 4*10²⁰ atoms/cm³ at 650° C. The solubility limit decreases at lower temperatures.

At 104, the method 100 can include depositing a first additional layer on the Ga and Ge layer. The first additional layer can include silicon (Si). The first additional layer can be a capping layer or an alloying layer. The capping layer can protect or seal the hyperdoped Ge from contaminants or other undesirable factors. The alloying layer can be used to alloy, include, incorporate Si into the hyperdoped Ge. The capping layer can have a thickness of less than 1 nm. The first additional layer can insulate the hyperdoped Ge. The first additional layer can form a uniform layer and match a crystal structure of the hyperdoped Ge. The alloying layer can have a thickness of less than 1 nm.

In various embodiments, the first additional layer can be a spacer layer. The first additional layer can include germanium. In such situations, the first additional layer can have a thickness between 1 to 2 nm, inclusive.

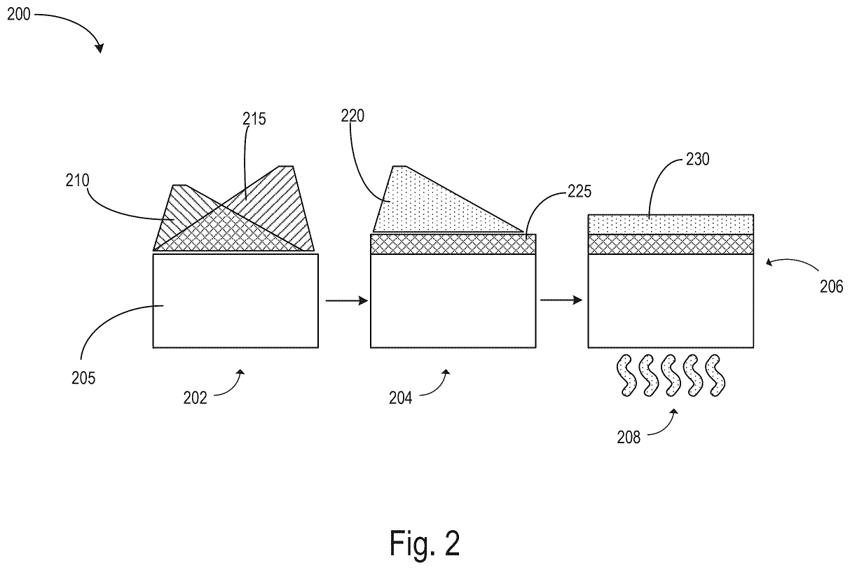

In one embodiment of the method 100 schematically shown in FIG. 2, a method 200 to illuminate a Ga dopant atom behavior can include room temperature co-deposition of Ga and Ge onto a Ge substrate at 202. The co-deposition can be followed by a capping layer of silicon under ultra-high vacuum (UHV) in a growth chamber at 204. Following the room temperature co-deposition of Ga and Ge on a Ge substrate and the capping layer of silicon, the capping layer of silicon can be oxidized in a chamber load lock at 206. The chamber load lock can be an intermediate environment between an external environment and the growth chamber. The chamber load lock can be a sealed chamber and can include a vacuum. A sample can include the Ge substrate, the Ga and Ge layers, and the capping layer of silicon. The sample can be re-introduced to the growth chamber following deposition of the capping layer of silicon. At 208, the sample can be flash annealed at 700° F. and cooled back down, emulating processing conditions of ion implantation samples. Flash annealing can be a rapid thermal processing technique. Ion implantation can be a technique that ionizes dopant atoms and accelerates the dopant atoms to a substrate. The method 200 can herein be referred to as a processing method 200. The processing method 200 can include a Ge substrate 205, a Ga flux 210, a Ge flux 215, a Si capping 220, a hyperdoped Ga:Ge layer 225, and a Si cap 230. The sample can include the Ge substrate 205, the hyperdoped Ga:Ge layer 225, and the Si cap 230. The processing method 200 can herein be referred to as Method A 200.

The Ge substrate 205 can include pure Ge. The Ge substrate 205 can be, but not limited to, a wafer or a plate. The Ge substrate 205 can be prepared to a specific crystal orientation, surface property, size, shape, and other characteristics through different processes, e.g., polishing, to ensure a uniformity of the Ge substrate 205.

The Ga flux 210 can be pure Ga. The Ga flux 210 can include individual molecular or atomic components of Ga. The Ga flux 210 can have a rate. The Ga flux 210 can be output by an electron beam evaporation source. The Ge flux 215 can be pure Ge. The Ge flux 215 can include individual molecular or atomic components of Ge. The Ge flux 215 can have a rate. The Ge flux 215 can be output by a Knudsen cell source. The Knudsen cell source can be designed, adapted, configured to generate a flux of evaporated material by thermal evaporation. The Ga flux 210 and the Ge flux 215 can deposit Ga and Ge onto the Ge substrate 205. The Ga flux 210 and the Ge flux 215 can deposit Ga and Ge onto the Ge substrate 205 at room temperature. The Si capping 220 can be pure Si. The Si capping 220 can include individual molecular or atomic components of Si. The Si capping 220 can have a rate. The Si capping 220 can be output by an electron beam evaporation source. The Si capping 220 can deposit Si onto the Ge substrate 205.

The hyperdoped Ga:Ge 225 can be a layer of Ge hyperdoped with Ga. The hyperdoped Ga:Ge 225 can be formed by the Ga flux 210 and the Ge flux 215 in a proportion (e.g., ratio). The proportion can be in a range of 1E12 to 6E12 Ga per centimeter squared (cm²) (e.g., quantity of Ga atoms in a cm² area of Ge, Ga/cm²). The hyperdoped Ga:Ge layer can have a number of Ga dopants higher than a solubility limit of Ga in Ge. The hyperdoped Ga:Ge 225 can be grown on the Ge substrate 205. The Si cap 230 can be a layer of pure Si. The Si cap 230 can be oxidized in the chamber load lock. The Si cap 230 can passivate and protect the sample from environmental factors or other factors that could affect the sample. The Si cap 230 can be formed by the Si capping 220. Following oxidation of the Si cap 230, the sample can be returned to the growth chamber and flash annealed at 700° F. and cooled back down. The Si cap 230 can be the second additional layer.

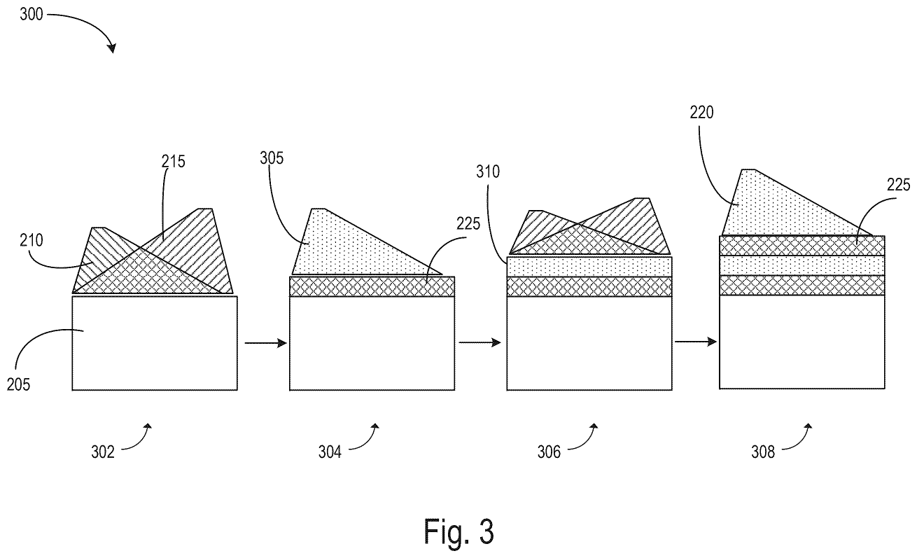

In another embodiment of the method 100 schematically shown in FIG. 3, a method 300 includes room temperature co-deposition of Ga and Ge onto a Ge substrate at 302. The Ga flux 210 and the Ge flux 215 can deposit Ga and Ge onto the Ge substrate 205 at room temperature. The method 300 can herein be referred to as the processing method 300. Halfway through growth of a superconducting layer, e.g., the hyperdoped Ga:Ge 225, growth can be paused and a thin, e.g., 1 nm, thick layer of silicon can be included at 304 before growth of Ga and Ge continues at 306. The layer of silicon can be greater than or less than 1 nm. The method 300 can include a Si flux 305 and a Si alloying layer 310. The Si flux 305 can be pure Si. The Si flux 305 can include individual molecular or atomic components of Si. The Si flux 305 can have a rate. The Si flux 305 can be output by an electron beam evaporation source.

The Si alloying layer 310 can alloy, deposit, be incorporated into the hyperdoped Ga:Ge layer 225. Deposition of Si at an intermediate stage of growth can introduce a small amount of Si that can alloy into a hyperdoped region, e.g., Ge hyperdoped with Ga, which can be expected to increase an average phonon frequency, ωₗₙ·ωₗₙ can be expected to give rise to an increased T_{c}, or superconducting transition temperature:

$${T}_{c} = \frac{h {ω}_{ln}}{1.2 {k}_{b}} Exp [ \frac{- 1.04 ( 1 + {λ}_{ep}}{{λ}_{ep} - {μ}^{*} ( 1 + 0.62 {λ}_{ep} )} ] \qquad Eq . 1$$

Where λₑₚ is the electron-phonon coupling parameter and μ* is the screened retarded Coulomb repulsion parameter. Equation 1 can herein be referred to as a McMillan formula. The sample can be capped with an additional layer of silicon (e.g., silicon cap 230) after completing the deposition of hyperdoped Ge at 308. No post-annealing may be performed for these samples. The processing method 300 can herein be referred to as Method B 300. Method B 300 can attempt to utilize the McMillan formula in Eq. 1 which suggests alloying with silicon to increase the average phonon frequency of the system (ωₗₙ), thus enhancing the observed T_{c} for a given density of states. Additionally, an increase in ωₗₙ can further be expected to also increase an electron-phonon coupling potential, Vₑₚ. By the relationship Vₑₚ=λₑₚ/N(E_{F}), where N(E_{F}) refers to the density of states at the Fermi level, it can be seen that an electron-phonon coupling parameter (λₑₚ) increases with the density of states. Both of these factors could contribute to an enhanced T_{c}.

In some embodiments, hyperdoped Ga:Ge, e.g., Ge hyperdoped with Ga, thin films were grown in a custom Varian Gen II MBE chamber on 2″ un-doped Ge (001) wafers. Prior to growth, wafers were etched ex-situ in DI-water at 90° C. and then immediately loaded into vacuum. The wafers were then outgassed in-situ at 400° C. for 30 minutes and then finally flash annealed at 650° C. for 5 minutes before cooling to a growth temperature. Pure germanium and silicon were deposited via Thermionics HM2 e-Gun operating with a 10 kV acceleration voltage. Gallium doping is done with a standard Knudsen cell source (MBE Komponenten). Substrates are mounted in indium-free bayonet style holders and a reported substrate temperatures are measured with a thermocouple in close proximity to a backside of the wafer. The substrate is rotated at a constant 10 rpm throughout film growth to promote uniformity.

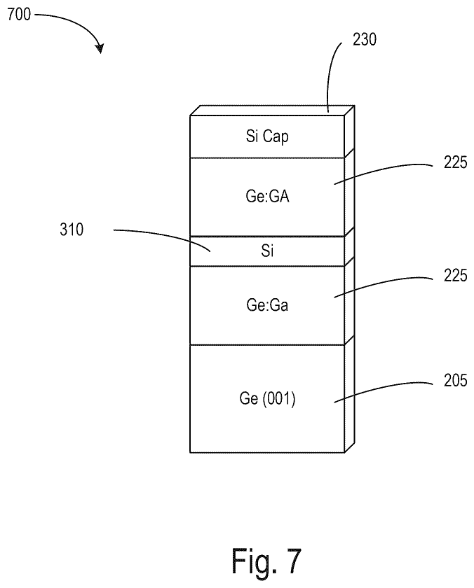

Referring now to FIG. 7, FIG. 7 depicts an example material 700 that can be produced by the method 300. The material 700 can include the Ge substrate 205, the hyperdoped Ga:Ge 225, the Si alloying layer 310, another hyperdoped Ga:G2 225, and the Si cap 230 deposited by the Si capping 220. In some embodiments, as shown in FIG. 7, the Si alloying layer 310 can have a thickness greater than or equal to 1 nm. For example the Si alloying layer 310 can have a thickness between 1 to 2 nm, inclusive. The Si alloying layer 310 can be the first additional layer 310. In some embodiments, the first additional layer 310 includes un-doped germanium instead of silicon.

### EXAMPLES

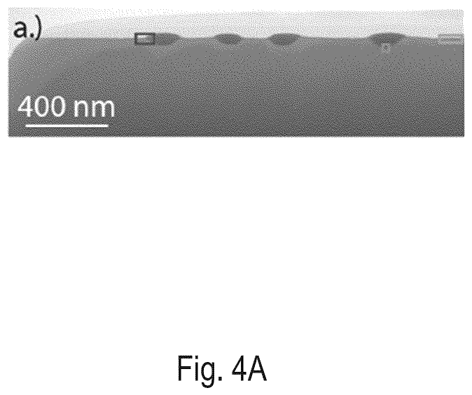

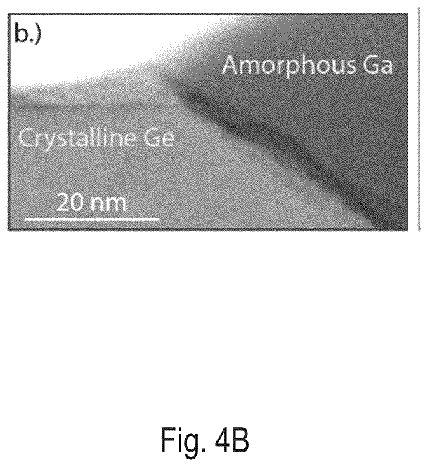

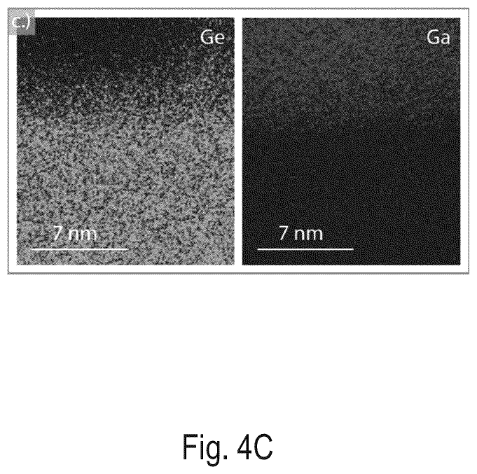

The crystallinity, compositional distribution, and film morphology of the films grown were examined with scanning transmission electron microscopy (STEM) in a JEOL ARM200F manufactured by JEOL Ltd. equipped with a spherical aberration corrector for probe mode and operated at 200 keV. The samples were prepared with cross-sectional tripod polishing to 20 μm thickness, followed by shallow angle Ar+ ion milling with low beam energies ([1]3 keV), and LN2 stage cooling in a PIPS II ion mill. Cross-sectional STEM images of a sample grown using Method A 200 are seen in FIG. 4A. Rapid annealing films under vacuum induces an extreme segregation of gallium metal out of a Ge matrix to form amorphous droplets on a surface of the substrate/film. These droplets selectively form in a near surface region and have a faint shadowing feature at a Ga-Ge interface which can be attributed to a heavy Ga-content in that region. Droplets on average are hundreds of nm in diameter, with a similar spacing separating the droplets from one another. The droplets are not isotropic and extend further into the substrate than they protrude from the surface.

FIG. 4A is a long-range bright field (“BF”) cross-sectional STEM images of a Ga-segregated Ge film scan showing significant segregation and agglomeration of Ga-droplets. Zooming into the interface between the droplet and the underlying Ge, an amorphous nature of the Ga metal can be confirmed, as seen in FIGS. 4B and 4C. This distinctly contrasts a crystalline nature of the underlying Ge. In this scenario, the Ga-rich regions exhibit significant out-diffusion of Ga metal which can be likely due to the high temperature anneal used to activate the Ga-dopants. This compositional shift can be confirmed through energy dispersive spectroscopy (“EDS”) maps, as depicted in FIG. 4C, of both a droplet region (blue) and a region between droplets (orange). FIG. 4C is a zoomed in view of the interface at a bottom of a droplet and the underlying Ge, depicted in FIG. 4A as the small blue box. A ˜5 nm thick Ga-rich Ge region can be seen before the composition becomes nearly pure Ga. Between droplets, as seen in the area highlighted in the orange box in FIG. 4A, a thin Ga-rich region can be seen on the order of few nanometers thick that serve as metallic interconnects between the Ga droplets.

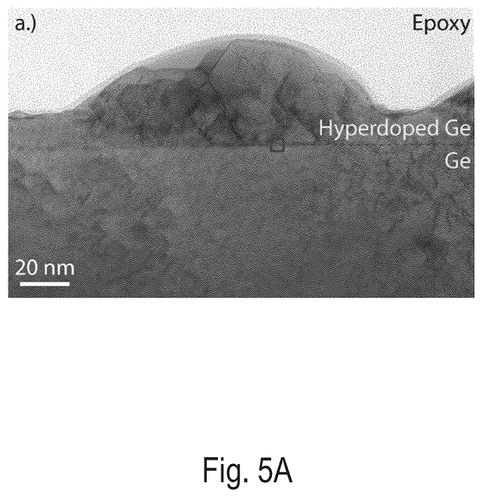

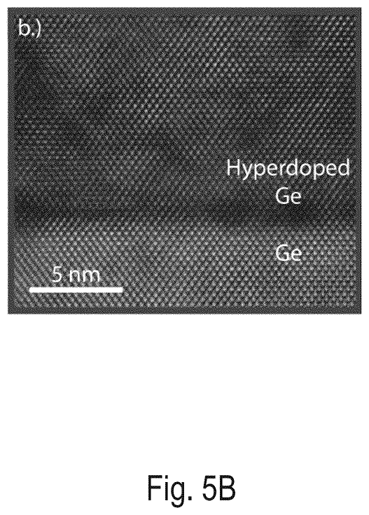

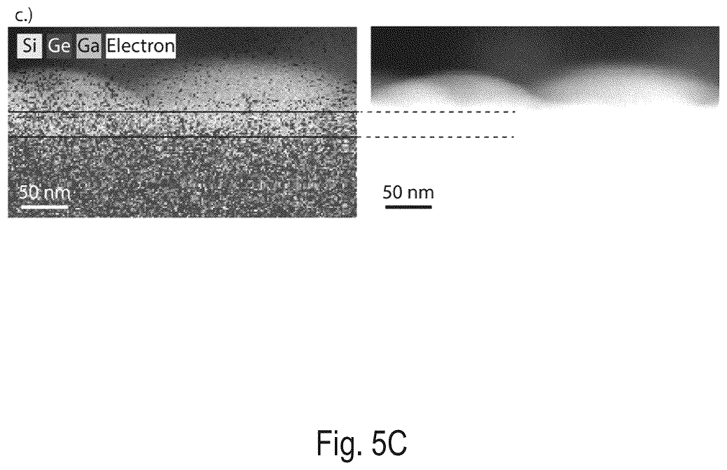

To suppress this Ga metal segregation, Method B 300 deposits the heavily doped layers at room temperature, however annealing at elevated temperatures does not occur. Removing the anneal step allows for maintaining a nominally consistent film composition and eliminates the observed Ga metal precipitates. Such behavior is pictured in FIG. 5B in which cross-sectional STEM images for a sample grown using Method B 300 present a fully connected film with an abrupt film/substrate interface.

FIGS. 5A-5C show a nominally sharp interface between the heavily doped region and the undoped germanium for Method B 300 samples which have no post-anneal for carrier activation. FIG. 5A shows a fully complete film coverage with no obvious signatures of significant Ga segregation, albeit the film is quite rough. Film roughness can be attributed to the difference island growth mechanism of Si on Ge during the Si cap growth. This behavior of the Si—Ge system has been previously observed and reported on. Furthermore, no obvious discontinuities can be observed in the atomic columns suggesting the Ge lattice is maintained as Ga has been incorporated.

FIG. 5C shows the EDS elemental mapping of a zoomed-out region showing elemental composition of the film. The interface between Ge and doped Ge is marked. The effective thickness of the doped Ge film is 5 nm before hillocks. The map also shows that hillocks are predominantly Ga-doped Si while in some places Ge is present. The continuous atomic registry is highly promising for continued development of coherent superconducting germanium thin films.

Electrical measurements are conducted in an Oxford Triton pulse-tube dilution refrigerator with a base temperature of 15 mK and magnetic field capabilities up to 14 T. Measurements are collected using a standard Van der Pauw wiring configuration on square pieces from near the center of each wafer. On-chip contacts are annealed In-Sn eutectic at each of the four corners.

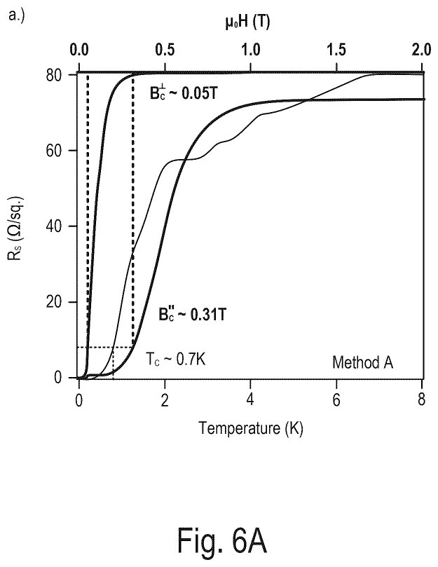

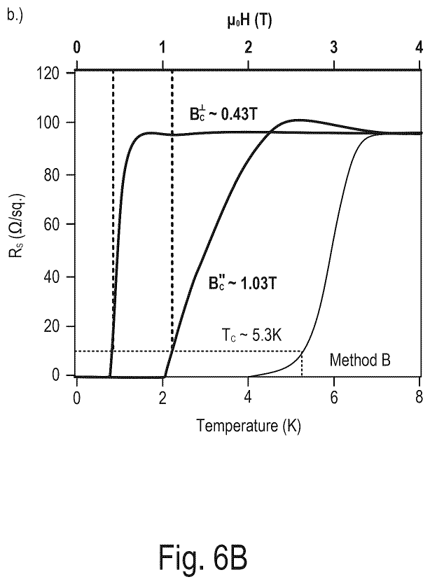

Transport measurements for both methods (e.g., Method A 200 and Method B 300) are presented in FIGS. 6A and 6B. In Ga-segregated films grown via Method A 200, the observed critical temperature of 0.89 K at zero field, and critical field values of

$${B}_{c}^{⊥} ∼ 0.05 T , and {B}_{c}^{‖} ∼ 310 mT$$

at T=15 mK, are highly suggestive of a Ga-metal origin. The transitions are marked by the 10% value of the normal resistance. Reported literature values for Ga of 1.1 K and 0.05 T, respectively, agree well with our measurements. The observed reduction in critical temperature is most likely due to the Ga droplets behaving as a weakly connected superconductor such that discrete “puddles” of superconducting Ga metal host the parent superconducting phase, but due to the low density, same T_{c} as bulk Ga was not observed. The enhanced in-plane field of 0.31 T can be attributed to the thin film nature of the superconducting film. FIG. 4A depicts a critical transition temperature near 0.7 K, with a critical out-of-plane magnetic field of roughly 50 mT and critical in-plane magnetic field of ˜310 mT.

Looking closer at the sheet resistance as a function of temperature, many kinks are observed between the range of ˜7 K and the total superconducting transition at 0.7 K. Kinks can be defects or discontinuities in a crystal structure of the hyperdoped Ge. The high temperature kinks can be attributed to the formation of Ga metal crystalline polymorphs as a result of the anneal, all of which have been shown previously to exhibit a superconducting transition temperature of 6 K or greater. The other features that are presented at more moderate temperatures ˜2-4 K are more difficult to confidently assign to Ga-related phases but could be due to either percolated Ga metal networks or sparse regions of hyperdoped Ge matrix.

FIG. 6B shows a different trend for samples grown using Method B 300. Samples grown using Method B 300 exhibit a transition temperature of near 5.3 K, with an enhanced critical out-of-plane field of 430 mT and critical in-plane field of ˜1.03 T. Here, significantly enhanced superconducting properties can be observed compared to that of the Ga-segregated films with T_{c}=5.27 K,

$${B}_{c}^{⊥} = 0.43 T , {B}_{c}^{‖} = 1.03 T .$$

Here sheet resistance versus temperature graph, a much sharper transition can be observed that starts ˜6.9 K and reaches the zero-resistance state at ˜5 K. Previous reports of superconductivity in Ga metal polymorphs have observed superconductivity at 6.9 K in ε-Ge and β-Ga at 6 K. Unfortunately, magnetic field behavior for many of these crystal polymorphs of Ga is not reported in literature, however reported values for nanoconfined particles of β-Ga are on the order of ˜430 Oe. While longer-extent transmission electron microscopy (“TEM”) images do show a single small β-Ga nanoparticle present in the focused ion beam (“FIB”) slice, the observed out-of-plane critical magnetic field exhibited by our hyperdoped Ge film is significantly larger than any reported values for crystalline phases of Ga. Thus, ruling out competing Ga phases as the origin of the observed superconductivity due to their sparsity in the film can be done. If the superconductivity observed here were a result of sparse interconnected grains of some alternative phase of Ga, a much larger transitional region could be expected, similar to the sample grown via Method A 200 and as has been reported previously in studies on Nb islands.

To help understand the superconducting phase in the sample grown using Method B 300, Hall measurements were conducted above B_{c}, in the Van der Pauw geometry and compare against the theorized quantities for an electronic origin. 2D hole concentration was measured of roughly 2.86×10¹²/cm² for the specific sample presented in this work, or a density of ˜1×10¹⁹/cm³ carriers. Comparing to previous reports of covalent superconductivity in this and related systems, not only is the transition temperature observed in this study significantly higher than is predicted for the Ge system (˜100 s mK), but also drastically lower carrier densities.

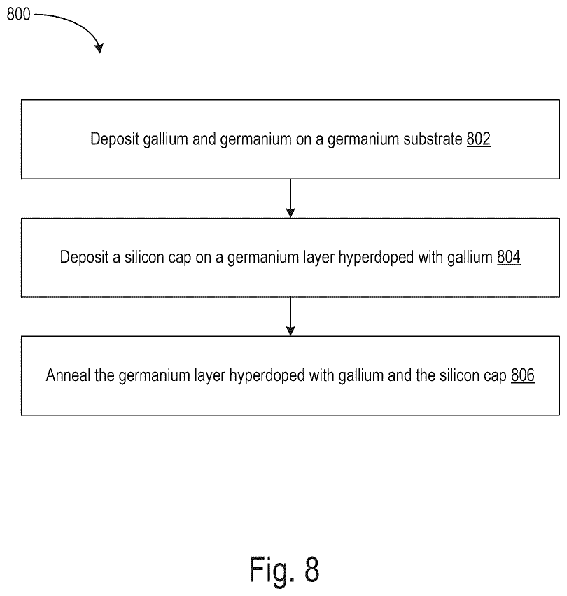

FIG. 8 is a flow diagram of an example method 800 for forming hyperdoped Ge. The method 800 can correspond to the method 200. The method 800, at block 802, can include depositing, via a gallium flux and a germanium flux, gallium and germanium on a germanium substrate at room temperature, where deposition of the gallium and germanium forms a germanium layer hyperdoped with gallium. The germanium layer hyperdoped with gallium can have a ratio of 1E12 to 6E12, inclusive, of gallium atoms per centimeter squared area of germanium

The method 800, at block 804, can include depositing, via a silicon flux, a silicon cap on the germanium layer hyperdoped with gallium. The method 800, at block 806, can include annealing the germanium substrate, the germanium layer hyperdoped with gallium, and the silicon cap. The method 800 can include oxidizing, after depositing the silicon cap and before annealing, the silicon cap, the germanium, layer hyperdoped with gallium, and the germanium substrate. The annealing of the germanium substrate can be flash annealing at a temperature greater than room temperature.

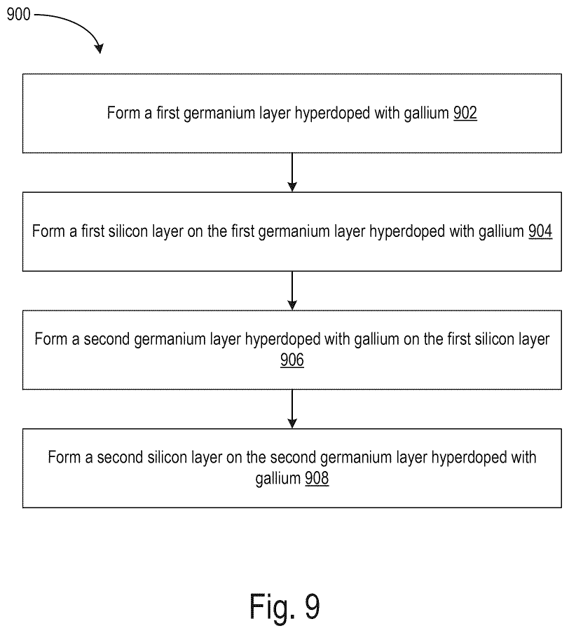

FIG. 9 is a flow diagram of an example method 900 for forming hyperdoped Ge. The method 900 can correspond to the method 300. The method 900, at block 902, can include forming, by depositing gallium and germanium on a germanium substrate, a first germanium layer hyperdoped with gallium. The method 900, at block 904, can include forming, by depositing silicon, a first silicon layer on the first germanium layer hyperdoped with gallium. The first silicon layer can be an alloying layer and can have a thickness of 1 nm or less. The thickness of the first silicon layer can be greater than 1 nm.

The method 900, at block 906, can include forming, by depositing gallium and germanium, a second germanium layer hyperdoped with gallium on the first silicon layer. The method 900, at block 908, can include forming, by depositing silicon, a second silicon layer on the second germanium layer hyperdoped with gallium. At least one of the first germanium layer hyperdoped with gallium, the first silicon layer, the second germanium layer hyperdoped with gallium, and or the second silicon layer can be formed by molecular beam epitaxy (MBE). At least one of the first germanium layer hyperdoped with gallium, the first silicon layer, the second germanium layer hyperdoped with gallium, or the second silicon layer can be formed at room temperature. At least one of the first germanium layer hyperdoped with gallium, the first silicon layer, the second germanium layer hyperdoped with gallium, or the second silicon layer can be formed under vacuum. At least one of the first germanium layer hyperdoped with gallium, the first silicon layer, the second germanium layer hyperdoped with gallium, or the second silicon layer can be flash annealed.

### Definitions

As used herein, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

As used herein, the terms “coupled,” “connected,” and the like mean the joining of two additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A method, comprising:
co-depositing, by molecular beam epitaxy (MBE), on a germanium substrate, a gallium-doped germanium layer at room temperature; and
depositing, on the gallium-doped germanium layer, a first additional layer.

2. The method of claim 1, wherein the gallium-doped germanium layer is hyperdoped with gallium.

3. The method of claim 1, wherein the first additional layer comprises silicon and is a capping layer.

4. The method of claim 3, wherein the gallium-doped germanium layer, and the first additional layer are oxidized.

5. The method of claim 4, wherein the germanium substrate, the gallium-doped germanium layer, and the first additional layer are flash annealed, the first additional layer comprising silicon.

6. The method of claim 1, wherein the first additional layer is deposited halfway through the co-depositing of the gallium-doped germanium layer.

7. The method of claim 6, wherein the first additional layer has a thickness of less than 1 nm.

8. The method of claim 6, wherein the first additional layer is an alloying layer.

9. The method of claim 6, wherein a second additional layer comprising silicon is deposited on the gallium-doped germanium layer.

10. The method of claim 6, wherein the first additional layer has a thickness between 1 to 2 nm, inclusive.

11. The method of claim 6, wherein the first additional layer is a spacer layer.

12. The method of claim 6, wherein the first additional layer comprises germanium.

13. The method of claim 9, where the second additional layer is a capping layer.

14. A method, comprising:
depositing, via a gallium flux and a germanium flux, gallium and germanium on a germanium substrate at room temperature, wherein deposition of the gallium and germanium forms a germanium layer hyperdoped with gallium;
depositing, via a silicon flux, a silicon cap on the germanium layer hyperdoped with gallium; and
annealing the germanium substrate, the germanium layer hyperdoped with gallium, and the silicon cap.

15. The method of claim 14, further comprising oxidizing, after depositing the silicon cap and before annealing, the silicon cap, the germanium, layer hyperdoped with gallium, and the germanium substrate.

16. The method of claim 14, wherein the germanium layer hyperdoped with gallium has a ratio of 1E12 to 6E12, inclusive, of gallium atoms per centimeter squared area of germanium.

17. The method of claim 14, wherein the annealing of the germanium substrate is flash annealing at a temperature greater than room temperature.

18. A method, comprising:
forming, by depositing gallium and germanium on a germanium substrate, a first germanium layer hyperdoped with gallium;
forming, by depositing silicon, a first silicon layer on the first germanium layer hyperdoped with gallium;
forming, by depositing gallium and germanium, a second germanium layer hyperdoped with gallium on the first silicon layer; and
forming, by depositing silicon, a second silicon layer on the second germanium layer hyperdoped with gallium.

19. The method of claim 18, wherein at least one of the first germanium layer hyperdoped with gallium, the first silicon layer, the second germanium layer hyperdoped with gallium, and or the second silicon layer are formed by molecular beam epitaxy (MBE).

20. The method of claim 18, wherein at least one of the first germanium layer hyperdoped with gallium, the first silicon layer, the second germanium layer hyperdoped with gallium, or the second silicon layer are formed at room temperature.
